(19) United States
(12) Patent Application Publication
(10) Pub. No.: US 2026/0031778 A1
(43) Pub. Date: Jan. 29, 2026

(54) OPERATIONAL AMPLIFIER

(71) Applicant: Himax Technologies Limited, Tainan City (TW)

(72) Inventors: Shih-Yang Liu, Tainan City (TW); Chen-Tung Lee, Tainan City (TW)

(21) Appl. No.: 18/787,906

(22) Filed: Jul. 29, 2024

(51) Int. Cl. H03F 3/45; H03F 1/30

(52) U.S. Cl. CPC H03F 3/45179; H03F 1/301; H03F 2203/45248

(57) ABSTRACT

An operational amplifier (OPA) includes an output stage composed of a P-type output transistor and an N-type output transistor connected in series between a power supply and ground, the N-type output transistor being controlled by a first control voltage and the P-type output transistor being controlled by a second control voltage; a first leakage eliminating circuit configured to prevent a sinking current through the N-type output transistor from entering the ground when an input voltage rises from a low voltage level to a high voltage level; and a second leakage eliminating circuit configured to prevent a sourcing current through the P-type output transistor from entering a load when the input voltage falls from the high voltage level to the low voltage level.

### BACKGROUND OF THE INVENTION

### 1. Field of the Invention

The present invention generally relates to an operational amplifier, and more particularly to an operational amplifier with reduced leakage current and enhanced slew rate.

### 2. Description of Related Art

The evolution of display technology in recent years has been impressive with a clear trend towards achieving higher specifications that cater to the demands of modern consumers. This progression is characterized by an emphasis on high screen resolution that offers more detailed and clearer images, and fast refresh rates that ensure smoother transitions and a better viewing experience, especially in dynamic scenes. Additionally, there is a growing importance placed on low power consumption, which not only extends the lifespan of devices but also aligns with the global push towards energy efficiency and sustainability.

In this landscape, the development of driver integrated circuits (ICs) becomes a cornerstone for meeting these advanced display specifications. Driver ICs serve as the bridge between the display technology and the device's processing unit, translating data into visual information. The focus on faster operational speeds and lower power usage within these ICs is crucial because it directly impacts the display's performance and the device's overall energy management.

At the heart of the driver ICs lies the operational amplifier (OPA), whose operational speed and power consumption are pivotal factors that influence the driver IC's performance. The OPA's role is to amplify the input signal to the levels required for the display's pixels to render images accurately. Therefore, the speed at which the OPA operates is critical. A high-speed OPA ensures that the display responds quickly to changes in the input signal, which is essential for high refresh rates.

Conversely, the power consumption of the OPA is equally important. A low-power OPA contributes to the overall energy efficiency of the device, reducing the power drain and thereby enhancing battery life in portable devices. It also minimizes heat generation, which can be a significant issue in compact devices where thermal management is a challenge.

Given these factors, designing a high-speed, low-power OPA is indeed critical for achieving superior display specifications. It requires a meticulous balance between speed and efficiency, often necessitating innovative design techniques and the use of advanced semiconductor materials that offer better performance without compromising on power consumption.

The implications of such advancements in OPAs extend beyond just improved display specifications. They contribute to the development of more sophisticated and energy-efficient electronic devices that can support the high-resolution, high-refresh-rate displays that are becoming increasingly common in the market. This, in turn, drives the industry forward, pushing the boundaries of what is possible in display technology and opening up new possibilities for consumer electronics.

In conclusion, as display technology continues to advance, the role of driver ICs, and particularly OPAs, becomes ever more significant. The industry's ability to design high-speed, low-power OPAs will be a determining factor in how far display technology can go, influencing everything from the next generation of smartphones to large-scale digital displays.

There is a significant challenge in the design of high slew rate OPAs. During the rising period, the rapid increase in output voltage may activate the NMOS transistor of the output stage due to capacitive coupling, leading to a substantial leakage current. Similarly, during the falling period, a swift decrease in output voltage may inadvertently turn on the PMOS transistor of the output stage, causing another form of unwanted leakage current. These issues are critical because they can affect the power consumption of the OPA. A need has thus arisen to carefully consider these effects and implement design strategies to minimize leakage currents and ensure reliable operation of the OPA in various conditions.

### SUMMARY OF THE INVENTION

In view of the foregoing, it is an object of the embodiment of the present invention to provide an operational amplifier (OPA) capable of substantially reducing leakage current and enhancing slew rate of the OPA.

The embodiment of the present invention aims to address two critical aspects of operational amplifier performance: leakage current and slew rate. By focusing on reducing leakage current, the operational amplifier can achieve higher efficiency. Simultaneously, enhancing the slew rate ensures that the amplifier can respond more quickly to changes in the input signal, making it suitable for high-speed operations. This dual focus on minimizing leakage and maximizing response speed could significantly improve the overall functionality of the operational amplifier.

According to one embodiment, an operational amplifier (OPA) includes an output stage composed of a P-type output transistor and an N-type output transistor, a first leakage eliminating circuit and a second leakage eliminating circuit. The P-type output transistor and the N-type output transistor are connected in series between a power supply and ground, the N-type output transistor is controlled by a first control voltage and the P-type output transistor is controlled by a second control voltage. The first leakage eliminating circuit is configured to prevent a sinking current through the N-type output transistor from entering the ground when an input voltage rises from a low voltage level to a high voltage level. The second leakage eliminating circuit is configured to prevent a sourcing current through the P-type output transistor from entering a load when the input voltage falls from the high voltage level to the low voltage level.

### BRIEF DESCRIPTION OF THE DRAWINGS

FIG. 1A shows a block diagram illustrating an operational amplifier (OPA) with reduced leakage current and enhanced slew rate according to one embodiment of the present invention;

FIG. 1B shows a circuit diagram of the OPA of FIG. 1A;

FIG. 1C shows a circuit diagram of the OPA of FIG. 1A configured as a non-inverting operational amplifier voltage follower;

FIG. 2A shows partial circuitry of the OPA of FIG. 1C illustrating operation when the input voltage rises from a low voltage level to a high voltage level;

FIG. 2B shows a timing diagram illustrating the input voltage and the output voltage pertinent to FIG. 2A;

FIG. 3A shows partial circuitry of the OPA of FIG. 1C illustrating operation when the input voltage Vin falls from a high voltage level to a low voltage level; and

FIG. 3B shows a timing diagram illustrating the input voltage and the output voltage pertinent to FIG. 3A.

### DETAILED DESCRIPTION OF THE INVENTION

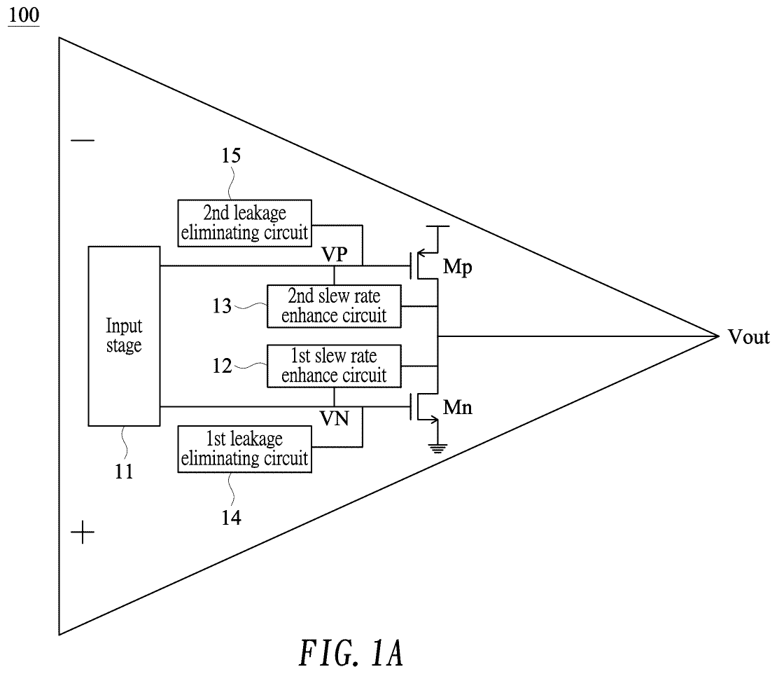

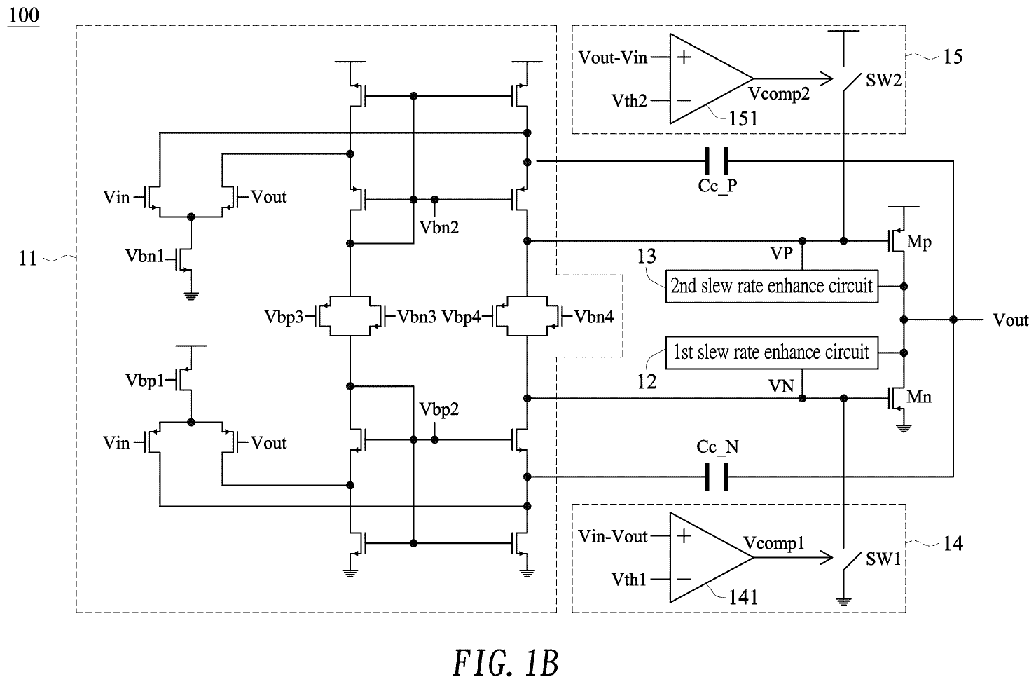

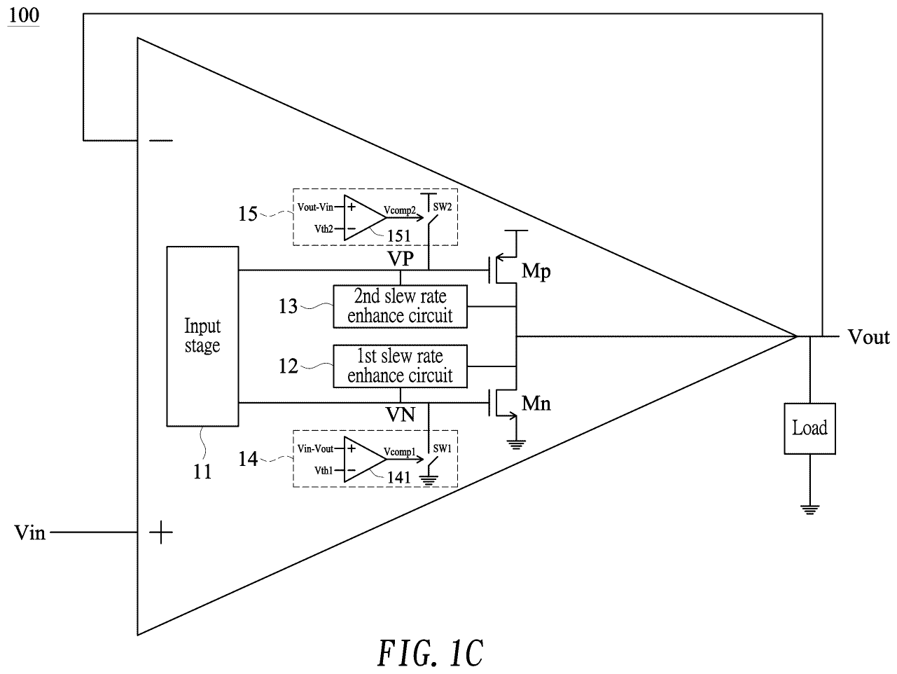

FIG. 1A shows a block diagram illustrating an operational amplifier (OPA) 100 with reduced leakage current and enhanced slew rate according to one embodiment of the present invention, and FIG. 1B shows a circuit diagram of the OPA 100 of FIG. 1A. The OPA 100 of the embodiment may, for example, be adaptable to a source driver for controlling individual pixels on a display, but is not limited thereto.

FIG. 1C shows a circuit diagram of the OPA 100 of FIG. 1A configured as a non-inverting operational amplifier voltage follower (or unity gain buffer) by directly connecting an output node Vout to an inverting input node (−) and being coupled to receive an input voltage Vin at a non-inverting input node (+). Accordingly, an output voltage Vout (at the output node Vout) directly follows and is identical to the input voltage Vin.

Specifically, the OPA 100 of the embodiment may include an output stage composed of a P-type output transistor Mp (e.g., metal-oxide-semiconductor field-effect transistor or MOSFET) and an N-type output transistor Mn (e.g., MOSFET) connected in series between a power supply and ground with a source of the P-type output transistor Mp connected to the power supply and a source of the N-type output transistor Mn connected to the ground. An interconnected node between the P-type output transistor Mp and the N-type output transistor Mn is used as the output node Vout, at which the output voltage Vout is generated. A gate of the N-type output transistor Mn is controlled by a first control voltage VN, and a gate of the P-type output transistor Mp is controlled by a second control voltage VP.

The OPA 100 of the embodiment may include an input stage 11 configured to generate the first control voltage VN and the second control voltage VP for controlling the N-type output transistor Mn and the P-type output transistor Mp respectively. In one exemplary embodiment, the input stage 11 may include a class-AB amplifier as shown in FIG. 1B, where Vbn1-Vbn4 and Vbp1-Vbp4 represent bias voltages for the class-AB amplifier.

The OPA 100 of the embodiment may include a first slew rate enhance circuit 12 configured to increase a sinking current, thereby facilitating quicker discharging of the output voltage Vout and enhancing slew rate of the OPA 100 when the input voltage Vin falls from a high voltage level (e.g., power supply) to a low voltage level (e.g., ground), and a second slew rate enhance circuit 13 configured to increase a sourcing current, thereby facilitating quicker charging of the output voltage Vout and enhancing slew rate of the OPA 100 when the input voltage Vin rises from a low voltage level to a high voltage level. Specifically, the first slew rate enhance circuit 12 may be connected between the output node Vout and a node that provides the first control voltage VN, and the second slew rate enhance circuit 13 may be connected between the output node Vout and a node that provides the second control voltage VP. The first slew rate enhance circuit 12 and the second slew rate enhance circuit 13 may be implemented by conventional techniques, details of which are omitted for brevity. The OPA 100 of the embodiment may further include compensation capacitors, such as Cc_N and Cc_P as shown in FIG. 1B, connected between the input stage 11 and the output stage Mp/Mn.

According to one aspect of the embodiment, the OPA 100 may include a first leakage eliminating circuit 14 configured to prevent a sinking current (flowing from the load and through the N-type output transistor Mn toward the ground) through the N-type output transistor Mn from entering the ground.

Specifically, the first leakage eliminating circuit 14 may include a first switch SW1 connected between the gate of the N-type output transistor Mn and the ground. The first leakage eliminating circuit 14 may include a first comparator 141 configured to compare a first difference voltage Vin-Vout with a first reference voltage Vth1, where the first difference voltage Vin-Vout represents the input voltage Vin minus the output voltage Vout. The first comparator 141 generates an active first compare output Vcomp1 to conduct (or turn on) the first switch SW1 when the first difference voltage Vin-Vout is greater than the first reference voltage Vth1, otherwise the first switch SW1 is disconnected (or turned off). In one embodiment, the first switch SW1 may be implemented by a (first) transistor with a threshold voltage to be approximately equal to the first reference voltage Vth1. It is appreciated that, for ease of understanding, the first comparator 141 is used to control the first switch SW1.

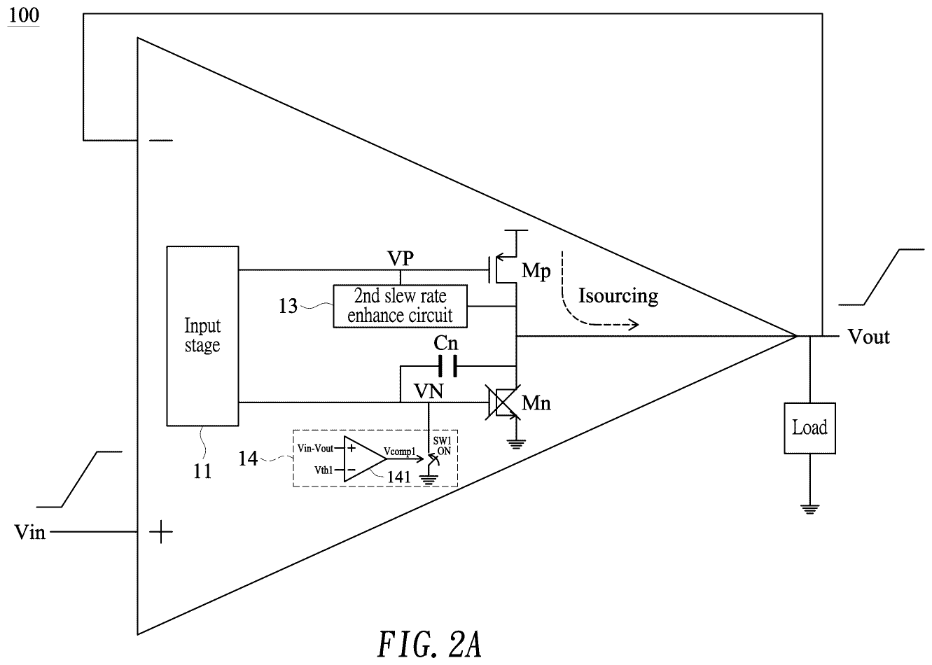

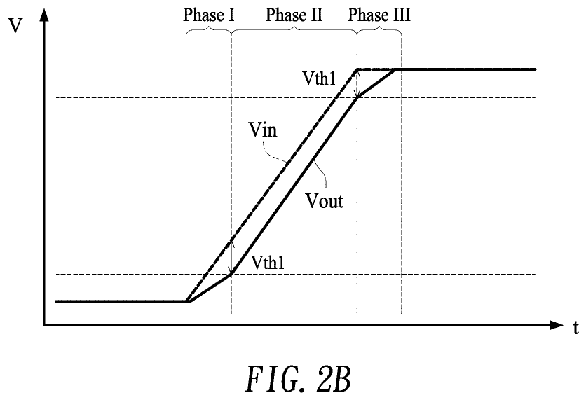

FIG. 2A shows partial circuitry of the OPA 100 of FIG. 1C illustrating operation when the input voltage Vin rises from a low voltage level (e.g., ground) to a high voltage level (e.g., power supply), and FIG. 2B shows a timing diagram illustrating the input voltage Vin and the output voltage Vout pertinent to FIG. 2A. Specifically, when the input voltage Vin rises, a sourcing current Isourcing flows through the P-type output transistor Mp toward the load and the output voltage Vout follows the input voltage Vin but with some delay.

In the first phase I, the first difference voltage Vin-Vout is not greater than the first reference voltage Vth1, thereby generating a passive first compare output Vcomp1 to disconnect the first switch SW1. In the second phase II, the first difference voltage Vin-Vout is greater than the first reference voltage Vth1, thereby generating an active first compare output Vcomp1 to conduct the first switch SW1. In the third phase III, the first difference voltage Vin-Vout is not greater than the first reference voltage Vth1, thereby generating a passive first compare output Vcomp1 to disconnect the first switch SW1. It is worth noting that, in the second phase II, the first control voltage VN at the gate of the N-type output transistor Mn is pulled to a low voltage level (i.e., ground), thereby turning off the N-type output transistor Mn and preventing the sinking current through the N-type output transistor Mn from entering ground as leakage current. Therefore, it can be ensured that the P-type output transistor Mp and the N-type output transistor Mn will not be turned on simultaneously, thereby substantially reducing significant leakage current flowing from the power supply to the ground. Moreover, the settling speed and the slew rate of the OPA 100 may be enhanced due to the elimination of the leakage current and the use of the second slew rate enhance circuit 13.

It is worth noting that if the first leakage eliminating circuit 14 is not adopted, the first control voltage VN may increase due to capacitive coupling effect, for example, owing to gate-to-drain parasitic capacitance Cn of the N-type output transistor Mn. As a result, the increased first control voltage VN consequently turns on the N-type output transistor Mn, thereby leading to significant leakage current and slow settling speed.

Referring back to FIG. 1A-FIG. 1C, according to another aspect of the embodiment, the OPA 100 may include a second leakage eliminating circuit 15 configured to prevent a sourcing current (flowing through the P-type output transistor Mp toward the load) through the P-type output transistor Mp from entering the load as leakage current.

Specifically, the second leakage eliminating circuit 15 may include a second switch SW2 connected between the gate of the P-type output transistor Mp and the power supply. The second leakage eliminating circuit 15 may include a second comparator 151 configured to compare a second difference voltage Vout-Vin with a second reference voltage Vth2, where the second difference voltage Vout-Vin represents the output voltage Vout minus the input voltage Vin. The second comparator 151 generates an active second compare output Vcomp2 to conduct the second switch SW2 when the second difference voltage Vout-Vin is greater than the second reference voltage Vth2, otherwise the second switch SW2 is disconnected. In one embodiment, the second switch SW2 may be implemented by a (second) transistor with a threshold voltage to be approximately equal to the second reference voltage Vth2. It is appreciated that, for ease of understanding, the second comparator 151 is used to control the second switch SW2.

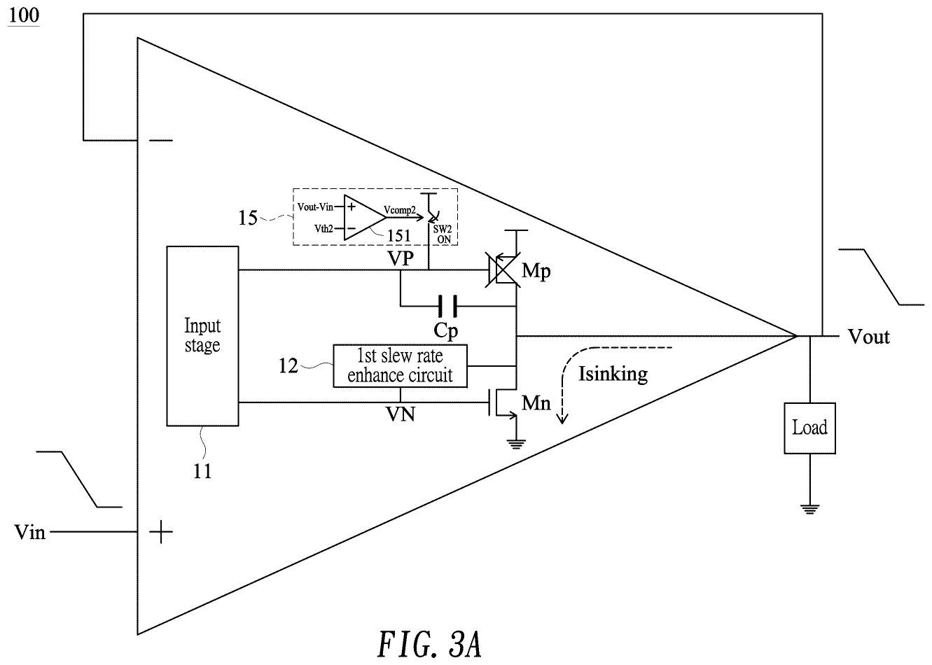

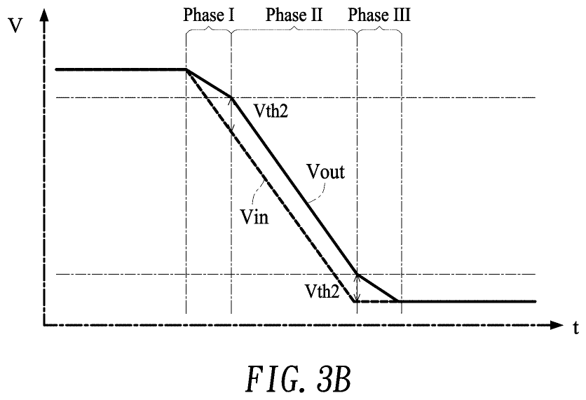

FIG. 3A shows partial circuitry of the OPA 100 of FIG. 1C illustrating operation when the input voltage Vin falls from a high voltage level (e.g., power supply) to a low voltage level (e.g., ground), and FIG. 3B shows a timing diagram illustrating the input voltage Vin and the output voltage Vout pertinent to FIG. 3A. Specifically, when the input voltage Vin falls, a sinking current Isinking flows from the load and through the N-type output transistor Mn toward the ground and the output voltage Vout follows the input voltage Vin but with some delay.

In the first phase I, the second difference voltage Vout-Vin is not greater than the second reference voltage Vth2, thereby generating a passive second compare output Vcomp2 to disconnect the second switch SW2. In the second phase II, the second difference voltage Vout-Vin is greater than the second reference voltage Vth2, thereby generating an active second compare output Vcomp2 to conduct the second switch SW2. In the third phase III, the second difference voltage Vout-Vin is not greater than the second reference voltage Vth2, thereby generating a passive second compare output Vcomp2 to disconnect the second switch SW2. It is worth noting that, in the second phase II, the second control voltage VP at the gate of the P-type output transistor Mp is pulled to a high voltage level (i.e., power supply), thereby turning off the P-type output transistor Mp and preventing the sourcing current through the P-type output transistor Mp from entering the load as leakage current. Therefore, it can be ensured that the P-type output transistor Mp and the N-type output transistor Mn will not be turned on simultaneously, thereby substantially reducing significant leakage current flowing from the power supply to the ground. Moreover, the settling speed and the slew rate of the OPA 100 may be enhanced due to the elimination of the leakage current and the use of the first slew rate enhance circuit 12.

It is worth noting that if the second leakage eliminating circuit 15 is not adopted, the second control voltage VP may decrease due to capacitive coupling effect, for example, owing to gate-to-drain parasitic capacitance Cp of the P-type output transistor Mp. As a result, the decreased second control voltage VP consequently turns on the P-type output transistor Mp, thereby leading to significant leakage current and slow settling speed.

According to the embodiment as disclosed above, by turning off the N-type output transistor Mn at the rising edge and the P-type output transistor Mp at the falling edge, direct current paths from the power supply to the ground are prevented. Therefore, reducing leakage current can improve power loss and thermal issues. Additionally, minimizing leakage current contributes to the improved settling speed of the OPA 100, allowing for faster response times and more efficient operation, thereby enhancing performance while conserving energy.

Although specific embodiments have been illustrated and described, it will be appreciated by those skilled in the art that various modifications may be made without departing from the scope of the present invention, which is intended to be limited solely by the appended claims.

What is claimed is:

1. An operational amplifier (OPA), comprising:
an output stage composed of a P-type output transistor and an N-type output transistor connected in series between a power supply and ground, the N-type output transistor being controlled by a first control voltage and the P-type output transistor being controlled by a second control voltage;
a first leakage eliminating circuit configured to prevent a sinking current through the N-type output transistor from entering the ground when an input voltage rises from a low voltage level to a high voltage level; and
a second leakage eliminating circuit configured to prevent a sourcing current through the P-type output transistor from entering a load when the input voltage falls from the high voltage level to the low voltage level.

2. The OPA of claim 1, wherein the first leakage eliminating circuit turns off the N-type output transistor when the input voltage rises from the low voltage level to the high voltage level, and the second leakage eliminating circuit turns off the P-type output transistor when the input voltage falls from the high voltage level to the low voltage level.

3. The OPA of claim 1, wherein the first leakage eliminating circuit pulls the first control voltage to the ground when the input voltage rises from the low voltage level to the high voltage level, and the second leakage eliminating circuit pulls the second control voltage to the power supply when the input voltage falls from the high voltage level to the low voltage level.

4. The OPA of claim 1, wherein a source of the P-type output transistor is connected to the power supply and a source of the N-type output transistor is connected to the ground.

5. The OPA of claim 1, wherein an interconnected node between the P-type output transistor and the N-type output transistor is used as an output node, at which an output voltage is generated.

6. The OPA of claim 5, wherein the output node is directly connected to an inverting input node, and a non-inverting input node is coupled to receive an input voltage.

7. The OPA of claim 1, further comprising:
an input stage that generates the first control voltage and the second control voltage for controlling the N-type output transistor and the P-type output transistor respectively.

8. The OPA of claim 7, wherein the input stage comprises a class-AB amplifier.

9. The OPA of claim 1, further comprising:
a first slew rate enhance circuit configured to increase a sinking current when the input voltage falls; and
a second slew rate enhance circuit configured to increase a sourcing current when the input voltage rises.

10. The OPA of claim 9, wherein the first slew rate enhance circuit is connected between an output node and a node that provides the first control voltage, and the second slew rate enhance circuit is connected between the output node and a node that provides the second control voltage.

11. The OPA of claim 1, wherein a gate of the N-type output transistor is controlled by the first control signal, and a gate of the P-type output transistor is controlled by the second control signal.

12. The OPA of claim 11, wherein the first leakage eliminating circuit comprises a first switch connected between the gate of the N-type output transistor and the ground, and the second leakage eliminating circuit comprises a second switch connected between the gate of the P-type output transistor and the power supply.

13. The OPA of claim 12, wherein the first switch is conducting, when the input voltage is greater than an output voltage and a difference therebetween is greater than a first reference voltage; and the second switch is conducting, when the output voltage is greater than the input voltage and a difference therebetween is greater than a second reference voltage.

14. The OPA of claim 13, wherein the first switch comprises a first transistor with a threshold voltage to be approximately equal to the first reference voltage, and the second switch comprises a second transistor with a threshold voltage to be approximately equal to the second reference voltage.
